(19) United States
(12) Patent Application Publication
(10) Pub. No.: US 2011/0262845 A1
(43) Pub. Date: Oct. 27, 2011

(54) METHOD FOR MODULATING LIGHT OF PHOTOREFRACTIVE COMPOSITION WITHOUT EXTERNAL BIAS VOLTAGE

(75) Inventors: Tao Gu, San Diego, CA (US); Weiping Lin, Carlsbad, CA (US); Peng Wang, San Diego, CA (US); Donald Flores, San Diego, CA (US); Michiharu Yamamoto, Carlsbad, CA (US)

(73) Assignee: Nitto Denko Corporation

(21) Appl. No.: 13/124,834

(22) PCT Filed: Sep. 18, 2009
(86) PCT No.: PCT/US09/57562

§ 371 Date: Jul. 7, 2011

Related U.S. Application Data
(60) Provisional application No. 61/106,859, filed on Oct. 20, 2008.

(51) Int. Cl. G03F 7/20; G03F 7/004

(52) U.S. Cl. 430/2

(57) ABSTRACT

A method for modulating light, comprising the steps of providing a photorefractive composition containing a sensitizer and a polymer, wherein the sensitizer includes at least one selected from the group consisting of anthraquinone, -nitro-9-fluorenone and 2,7-dinitro-9-fluorenone and irradiating the photorefractive composition with a laser. The photorefractive composition provides a grating without using an external bias voltage.

### CROSS-REFERENCE TO RELATED APPLICATIONS

This application claims priority to U.S. Provisional Application Ser. No. 61/106,859 filed on Oct. 20, 2008, entitled “METHOD FOR MODULATING LIGHT OF PHOTOREFRACTIVE COMPOSITION WITHOUT EXTERNAL BIAS VOLTAGE,” the contents of which are hereby incorporated by reference in their entirety.

### BACKGROUND OF THE INVENTION

1. Field of the Invention

The invention relates to a method of forming a grating in a photorefractive composition using a photorefractive composition comprising a sensitizer and a polymer. The photorefractive composition may be configured to be photorefractive upon irradiation by a laser and to provide a grating without using external bias voltage. The polymer comprises a repeating unit including a moiety selected from the group consisting of the carbazole moiety, tetraphenyl diaminobiphenyl moiety, and triphenylamine moiety. Embodiments of the composition can be used for various applications and devices, including holographic data storage and image recording materials.

2. Description of the Related Art

Photorefractivity is a phenomenon in which the refractive index of a material can be altered by changing the electric field within the material, such as by laser beam irradiation. The change of the refractive index typically involves: (1) charge generation by laser irradiation, (2) charge transport, resulting in the separation of positive and negative charges, (3) trapping of one type of charge (charge delocalization), (4) formation of a non-uniform internal electric field (space-charge field) as a result of charge delocalization, and (5) a refractive index change induced by the non-uniform electric field. Good photorefractive properties are typically observed in materials that combine good charge generation, charge transport or photoconductivity, and electro-optical activity. Photorefractive materials have many promising applications, such as high-density optical data storage, dynamic holography, optical image processing, phase conjugated mirrors, optical computing, parallel optical logic, and pattern recognition. Particularly, long lasting grating behavior can contribute significantly for high-density optical data storage or holographic display applications.

Originally, the photorefractive effect was found in a variety of inorganic electro-optical crystals, such as LiNbO₃. In these materials, the mechanism of a refractive index modulation by the internal space-charge field is based on a linear electro-optical effect.

In 1990 and 1991, the first organic photorefractive crystal and polymeric photorefractive materials were discovered and reported. Such materials are disclosed, for example, in U.S. Pat. No. 5,064,264, the contents of which are hereby incorporated by reference in their entirety. Organic photorefractive materials offer many advantages over the original inorganic photorefractive crystals, such as large optical nonlinearities, low dielectric constants, low cost, lightweight, structural flexibility, and ease of device fabrication. Other important characteristics that may be desirable depending on the application include sufficiently long shelf life, optical quality, and thermal stability. These kinds of active organic polymers are emerging as key materials for advanced information and telecommunication technology.

In recent years, efforts have been made to improve the properties of organic, and particularly polymeric, photorefractive materials. Various studies have been done to examine the selection and combination of the components that give rise to each of these features. Photoconductive capability can be provided by incorporating materials containing carbazole groups. Phenyl amine groups can also be used for the charge transport portion of the material.

The photorefractive composition may be made by mixing molecular components that provide desirable individual properties into a host polymer matrix. However, previously prepared compositions generally must be written and read out with a large external electric field. For a variety of holographic applications, such as data storage, using a large amount of voltage to read data creates the risk of losing data or otherwise causing disorder to the data. Efforts have been made, therefore, to provide compositions which are photorefractive without applying external bias voltage.

U.S. Patent App. Pub. No. 2008/0039603 and U.S. Pat. No. 6,653,421, the contents of which are both hereby incorporated by reference in their entirety, disclose (meth)acrylate-based polymers and copolymer based materials which are sensitive to green laser and red laser respectively. JP-2006-171320-A and JP-2004-258604 both disclose methods of making PVK and carbazole type photorefractive compositions, which exhibit good diffraction efficiency without external voltage.

Also, several photorefractive polymers were previously demonstrated in Peng et al., “Synthesis and Characterization of Photorefractive Polymers Containing Transition Metal Complexes as Photosensitizer,” J. Amer. Chem. Soc., 119(20), 4622 (1997) and Darracq et al., “Stable photorefractive memory effect in sol-gel materials,” Appl. Phys. Lett., 70, 292 (1997). A material with long grating holding possesses the ability to exhibit grating signal behavior for hours, even days, after irradiation. Optical devices with these properties are useful for various applications, such as data or image storage. Thus, there remains further need for optical devices comprising materials that provide good photorefractivity performances without needing application of large external bias voltage.

### SUMMARY OF THE INVENTION

An embodiment of the present invention provides a photorefractive composition and methods of using thereof, wherein grating can be written and grating signals can be read out without the use of large external bias voltage. Additionally, the grating can be held for long periods of time, for example, hours to days for holographic applications. Embodiments of the organic based materials and holographic medium described herein show good diffraction efficiencies in response to visible light laser beams, particularly light having a wavelength of from about 500 nm to about 700 nm. The availability of such materials that are sensitive to a continuous wave laser system can be greatly advantageous and useful for various industrial applications.

An embodiment provides a method of forming a grating in a photorefractive composition comprising the steps of providing a photorefractive composition responsive to a visible light laser beam, wherein the photorefractive composition comprises a sensitizer and a hole-transfer type polymer which exhibits good phase stability. In an embodiment, the sensitizer comprises at least one selected from the group consisting of anthraquinone, 2-nitro-9-fluorenone and 2,7-dinitro-9-fluorenone, and the polymer comprises at least a repeating unit including a moiety selected from the group consisting of a carbazole moiety, a tetraphenyl diaminobiphenyl moiety, and a triphenylamine moiety. In some embodiment, the composition can be used for holographic applications, such as holographic data storage, as image recording materials, and in optical devices. In an embodiment, the method comprises irradiating the photorefractive composition with a visible light laser beam without applying an external bias voltage. A grating is formed in the photorefractive composition upon irradiation. Light is modulated upon grating formation.

In an embodiment, the polymer in the photorefractive composition comprises a repeating unit that includes at least one moiety selected from the group consisting of the following formulae:

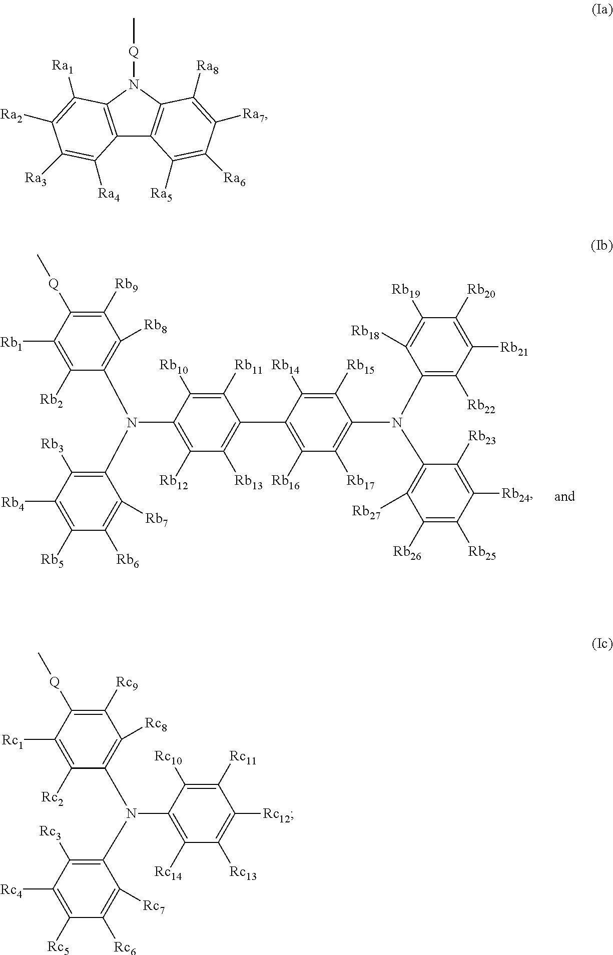

wherein each Q in formulae (Ia), (Ib) and (Ic) independently represents an alkylene or a heteroalkylene; Ra₁-Ra₈, Rb₁-Rb₂₇, and Rc₁-Rc₁₄ in formulae (Ia), (Ib), and (Ic) are each independently selected from the group consisting of hydrogen, linear or branched optionally substituted C₁-C₁₀ alkyl or heteroalkyl, and optionally substituted C₆-C₁₀ aryl.

### DETAILED DESCRIPTION OF THE INVENTION

Conventional photorefractive compositions are responsive to visible light laser beam irradiation with the application of a large external bias voltage. However, preferred photorefractive compositions described herein exhibit photorefractive behavior to a visible light laser beam with little or no use of external bias voltage. In an embodiment, the photorefractive composition comprises a sensitizer and a polymer. In an embodiment, the polymer comprises a first repeating unit that include at least one moiety selected from the group consisting of the carbazole moiety (represented by formula (Ia)), tetraphenyl diaminobiphenyl moiety (represented by the formula (Ib)), and triphenylamine moiety (represented by the formula (Ic)).

Each of the alkyl, heteroalkyl, or aryl groups in formulae (Ia), (Ib), and (Ic) can be “optionally substituted” with one or more substituent group(s). When substituted, the substituent group(s) is(are) one or more group(s) individually and independently selected from alkyl, alkenyl, alkynyl, cycloalkyl, cycloalkenyl, cycloalkynyl, aryl, heteroaryl, heteroalicyclyl, aralkyl, heteroaralkyl, (heteroalicyclyl)alkyl, hydroxy, protected hydroxyl, alkoxy, aryloxy, acyl, ester, mercapto, alkylthio, arylthio, cyano, halogen, carbonyl, thiocarbonyl, O-carbamyl, N-carbamyl, O-thiocarbamyl, N-thiocarbamyl, C-amido, N-amido, S-sulfonamido, N-sulfonamido, C-carboxy, protected C-carboxy, O-carboxy, isocyanato, thiocyanato, isothiocyanato, nitro, silyl, sulfenyl, sulfinyl, sulfonyl, haloalkyl, haloalkoxy, trihalomethanesulfonyl, trihalomethanesulfonamido, and amino, including mono- and di-substituted amino groups, and the protected derivatives thereof. Non-limiting examples of the substituent group(s) include, for example, methyl, ethyl, propyl, butyl, pentyl, isopropyl, methoxide, ethoxide, propoxide, isopropoxide, butoxide, pentoxide and phenyl.

The alkylene or heteroalkylene groups represented by Q in the various formulae described herein, including formulae (Ia), (Ib) and (Ic), can comprise from 1 to about 20 carbon atoms. In an embodiment, Q in formulae (Ia), (Ib) and (Ic) is selected from the group consisting of ethylene, propylene, butylene, pentylene, hexylene, and heptylene, each of which may optionally contain a heteroatom, such as O, N, or S. The heteroalkylene group can comprise one or more heteroatoms. Any heteroatom or combination of heteroatoms can be used, including O, N, S, and any combination thereof

In some embodiments, the polymer comprising a first repeating unit that includes at least one of formulae (Ia), (Ib), and (Ic) may be polymerized or copolymerized to form a charge transport component of a photorefractive composition. In some embodiments, for example, a polymer comprising a first repeating unit that includes only one of the moieties alone may be polymerized to form a photorefractive polymer. In some embodiments, for example, two or more of the moieties may also be present in a copolymer to form a photorefractive polymer. The polymer or copolymer that includes one, two, or even three of these moieties preferably possesses the charge transport ability.

Each of the moieties of formulae (Ia), (Ib), and (Ic) can be attached to a polymer backbone. Many polymer backbone, including but not limited to, polyurethane, epoxy polymers, polystyrene, polyether, polyester, polyamide, polyimide, polysiloxane, and polyacrylate, with the appropriate side chains attached, can be used to make the polymers of the photorefractive composition. Some embodiments contain backbone units based on acrylates or styrene, and some of preferred backbone units are formed from acrylate-based monomers, and some are formed from methacrylate monomers. It is believed that the first polymeric materials to include photoconductive functionality in the polymer itself were the polyvinyl carbazole materials developed at the University of Arizona. However, these polyvinyl carbazole polymers tend to become viscous when subjected to some of the heat-processing methods used to form the polymer into films or other shapes for use in photorefractive devices.

The (meth)acrylate-based and acrylate-based polymers used in embodiments described herein have improved thermal and mechanical properties. The polymers described herein provide good durability and workability during processing by injection-molding or extrusion, especially when the polymers are prepared by radical polymerization. Some embodiments provide a composition comprising a sensitizer and a photorefractive polymer that is activated upon irradiation by a visible light laser beam, wherein the photorefractive polymer comprises a repeating unit selected from the group consisting of the following formulae:

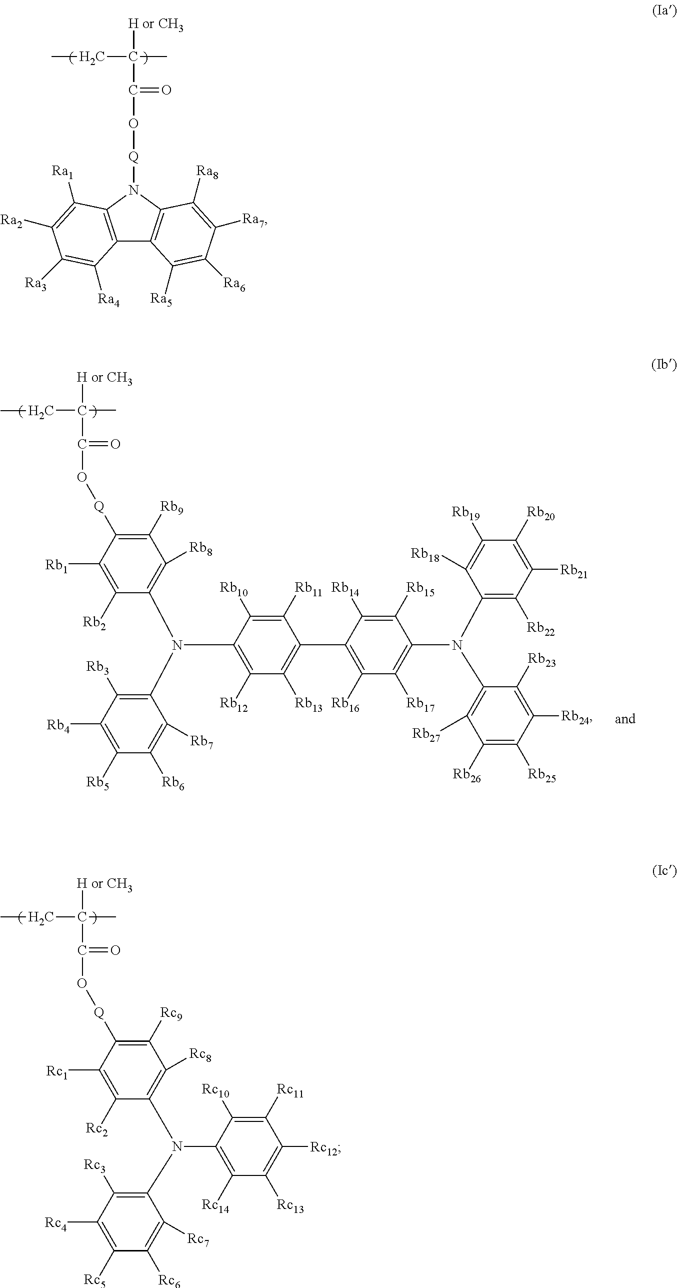

In an embodiment, each Q in formulae (Ia′), (Ib′) and (Ic′) independently represents an alkylene group or a heteroalkylene group. In an embodiment, Ra₁-Ra₈, Rb₁-Rb₂₇ and Rc₁-Rc₁₄ in formulae (Ia′), (Ib′) and (Ic′) are each independently selected from the group consisting of hydrogen, linear or branched optionally substituted C₁-C₁₀ alkyl or heteroalkyl, and optionally substituted C₆-C₁₀ aryl. The hetero atom in the heteroalkylene group or the heteroalkyl group can have one or more heteroatoms selected from S, N, or O.

In some embodiments, a polymer comprising at least one repeating unit that includes a moiety of at least one of formulae (Ia′), (Ib′) and (Ic′) can also be polymerized or copolymerized to form a photorefractive polymer that provides charge transport ability. In some embodiments, monomers comprising a phenyl amine derivative can be copolymerized to form the charge transport component as well. Non-limiting examples of such monomers are carbazolylpropyl(meth)acrylate monomer; 4-(N,N-diphenylamino)-phenylpropyl(meth)acrylate; N-[(meth)acroyloxypropylphenyl]-N,N′,N′-triphenyl-(1,1′-biphenyl)-4,4′-diamine; N-[(meth)acroyloxypropylphenyl]-N′-phenyl-N, N′-di(4-methylphenyl)-(1,1′-biphenyl)-4,4′-diamine; and N-[(meth)acroyloxypropylphenyl]-N′-phenyl-N,N′-di(4-buthoxyphenyl)-(1,1′-biphenyl)-4,4′-diamine. These monomers can be used to form polymer by themselves or to form copolymers, e.g., by polymerization of a mixture of two or more monomers.

In preferred embodiments the photorefractive composition described herein can be configured or formulated to be photorefractive upon irradiation with a visible light laser by incorporation of a sensitizer. The sensitizers described herein also allow for gratings to be written and read out of the composition without using an external bias voltage. In an embodiment, the composition is formulated to be capable of providing a grating without external bias voltage. In an embodiment, the photorefractive composition is formulated such that a grating that is irradiated into the photorefractive composition can be read out without applying external bias voltage. The sensitizer can be added into the composition as a mixture with the polymer and/or be directly bonded to the polymer, e.g., by covalent or other bonding.

In an embodiment, a sensitizer comprises at least one selected from the group consisting of anthraquinone, 2-nitro-9-fluorenone and 2,7-dinitro-9-fluorenone:

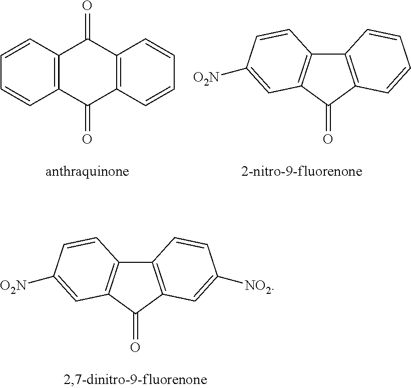

Any combination of one or more of the above sensitizers can be used, and the total amount of sensitizer can vary. In an embodiment, the amount of the sensitizer in the photorefractive composition is in the range of about 0.01% to about 10%, based on the weight of the composition. In an embodiment, the amount of the sensitizer in the photorefractive composition is in the range of about 0.1% to about 7%, based on the weight of the composition. In an embodiment, the amount of the sensitizer in the photorefractive composition is in the range of about 1% to about 5%, based on the weight of the composition. In an embodiment, the amount of the sensitizer in the photorefractive composition is in the range of about 2% to about 4%, based on the weight of the composition.

In an embodiment, the photorefractive composition further comprises a sensitizer other than anthraquinone, 2-nitro-9-fluorenone and 2,7-dinitro-9-fluorenone. For example, a fullerene can be added to the composition. “Fullerenes” are carbon molecules in the form of a hollow sphere, ellipsoid, tube, or plane, and derivatives thereof. One example of a spherical fullerene is C₆₀. While fullerenes are typically comprised entirely of carbon molecules, fullerenes may also be fullerene derivatives that contain other atoms, e.g., one or more substituents attached to the fullerene. In an embodiment, the sensitizer is a fullerene selected from C₆₀, C₇₀, C₈₄, each of which may optionally be substituted. In an embodiment, the fullerene is selected from soluble C₆₀ derivative [6,6]-phenyl-C61-butyricacid-methylester, soluble C₇₀ derivative [6,6]-phenyl-C₇₁-butyricacid-methylester, or soluble C₈₄ derivative [6,6]-phenyl-C₈₅-butyricacid-methylester. Fullerenes can also be in the form of carbon nanotubes, either single-wall or multi-wall. The single-wall or multi-wall carbon nanotubes can be optionally substituted with one or more substituents.

In some embodiments, the photorefractive composition further comprises an additional component that has non-linear optical functionality, e.g., a chromphore. Moieties or chromophores can be any group known in the art to provide non-linear optical capability. Moieties or chromophores with non-linear optical functionality may be incorporated into the polymer matrix as an additive to the composition or as functional groups attached to monomers to be copolymerized.

For example, the photorefractive composition may comprise additional repeating unit having one or more non-linear optical moiety. In some embodiments, the non-linear optical moiety may be presented as a side chain on a polymer backbone that allows copolymerization with polymers with charge transport moieties. In an embodiment, the photorefractive polymer further comprises a second repeating unit represented by the following formula:

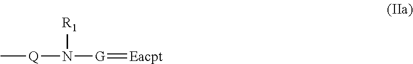

wherein Q in formula (IIa) represents an alkylene group or a heteroalkylene group, the heteroalkylene group has one or more heteroatoms selected from S or O; R₁ in formula (IIa) is selected from the group consisting of hydrogen, linear or branched C ₁-C₁₀ alkyl, and C₆-C₁₀ aryl; G in formula (IIa) is a π-conjugated group; and Eacpt in formula (IIa) is an electron acceptor group. In some embodiments, R₁ in formula (IIa) is an alkyl group selected from methyl, ethyl, propyl, butyl, pentyl, and hexyl. In some embodiments, Q in formula (IIa) is an alkylene group represented by (CH₂)ₚ where p is in the range of about 2 to about 10. In some embodiments, Q in formula (IIa) is selected from the group consisting of ethylene, propylene, butylene, pentylene, hexylene, and heptylene.

In some embodiments, the photorefractive polymer comprises a second repeating unit represented by the following formula:

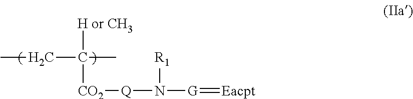

wherein Q in formula (IIa′) represents an alkylene group or a heteroalkylene group, the heteroalkylene group has one or more heteroatom such as S or O; R₁ in formula (IIa′) is selected from the group consisting of hydrogen, linear or branched C₁-C₁₀ alkyl, and C₆-C₁₀ aryl; G in formula (IIa′) is a π-conjugated group and Eacpt in formula (IIa′) is an electron acceptor group. In some embodiments, R₁ in formula (IIa′) is an alkyl group selected from methyl, ethyl, propyl, butyl, pentyl and hexyl. In some embodiments, Q in formula (IIa′) is an alkylene group represented by (CH₂)ₚ where p is in the range of about 2 to about 10. In some embodiments, Q in formula (IIa′) is selected from the group consisting of ethylene, propylene, butylene, pentylene, hexylene, and heptylene.

The term “π-conjugated group” refers to a molecular fragment that contains π-conjugated bonds. The π-conjugated bonds refer to covalent bonds between atoms that have σ bonds and π bonds formed between two atoms by overlapping of atomic orbits (s+p hybrid atomic orbits for σ bonds and p atomic orbits for π bonds). In some embodiments, G in formulae (IIa) and (IIa′) is independently represented by a formula selected from the following:

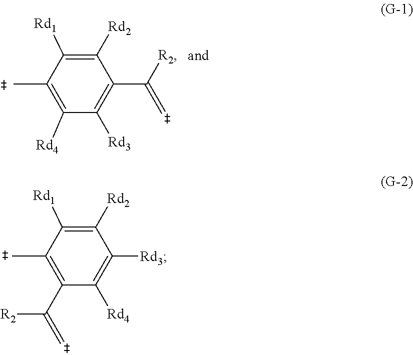

wherein Rd₁-Rd₄ in formulae (G-1) and (G-2) are each independently selected from the group consisting of hydrogen, linear or branched C₁-C₁₀ alkyl, C₆-C₁₀ aryl, and halogen and R₂ in formulae (G-1) and (G-2) is independently selected from the group consisting of hydrogen, linear or branched C₁-C₁₀ alkyl, and C₆-C₁₀ aryl.

The term “electron acceptor group” refers to a group of atoms with a high electron affinity that can be bonded to a π-conjugated group. Exemplary acceptors, in order of increasing strength, are: C(O)NR²<C(O)NHR<C(O)NH₂<C(O)OR<C(O)OH<C(O)R<C(O)H<CN<S(O)₂R<NO₂, wherein each R in these electron acceptors may independently be, for example, hydrogen, linear or branched C₁-C₁₀ alkyl, or C₆-C₁₀ aryl. As shown in U.S. Pat. No. 6,267,913, examples of electron acceptor groups include:

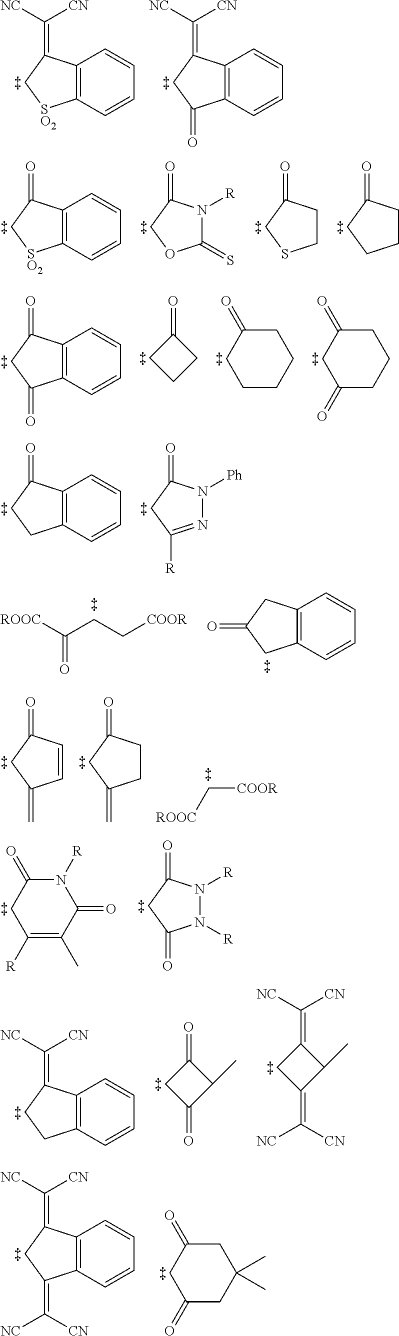

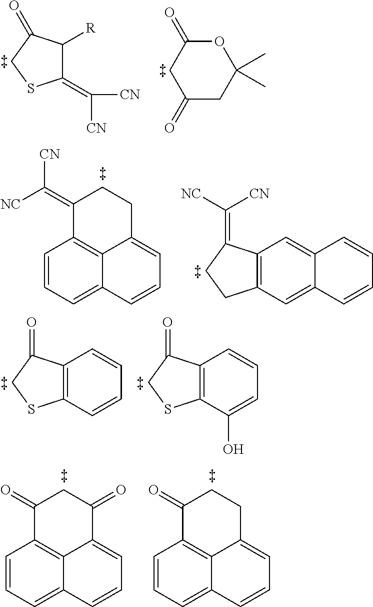

wherein R in each of the above compounds is independently selected from the group consisting of hydrogen, linear or branched C₁-C₁₀ alkyl, and C₆-C₁₀ aryl. The symbol “‡” in a chemical structure specifies an atom of attachment to another chemical group and indicates that the structure is missing a hydrogen that would normally be implied by the structure in the absence of the “‡”.

In some embodiments, Eacpt in formulae (IIa) and (IIa′) may be oxygen or independently represented by a structure selected from the group consisting of the following formulae (E-2) to (E-6):

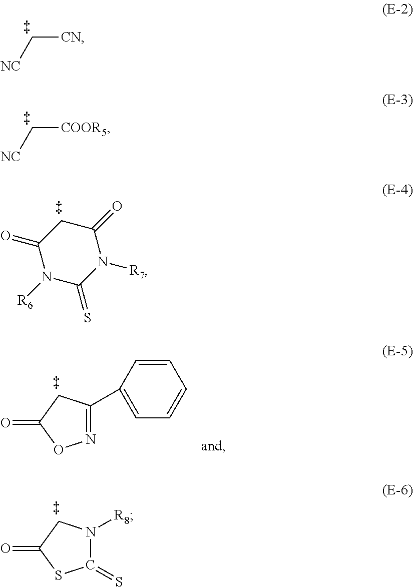

wherein R₅, R₆, R₇ and R₈ in the above formulae are each independently selected from the group consisting of hydrogen, linear or branched C₁-C₁₀ alkyl, and C₆-C₁₀ aryl.

To prepare the non-linear optical component-containing copolymer, monomers that have side-chain groups possessing non-linear-optical ability may be used. Non-limiting examples of such monomers include:

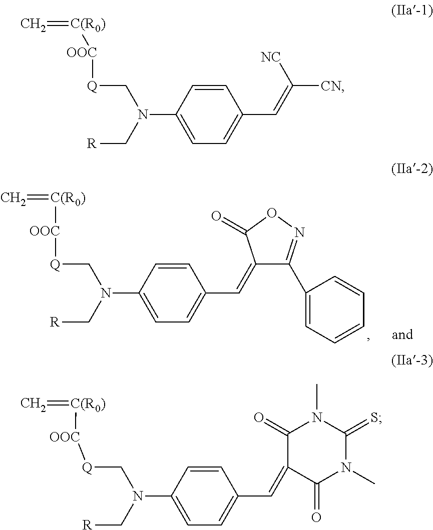

wherein each Q in the monomers above independently represent an alkylene group or a heteroalkylene group, the heteroalkylene group has one or more heteroatoms such as O, N, and S; each R₀ in the monomers above is independently selected from hydrogen or methyl; and each R in the monomers above is independently selected from linear or branched C₁-C₁₀ alkyl. In some embodiments, Q in the monomers above may be an alkylene group represented by (CH₂)ₚ where p is in the range of about 2 to about 6. In some embodiments, each R in the monomers above may be independently selected from the group consisting of methyl, ethyl and propyl.

In some embodiments, monomers comprising a chromophore, can also be used to prepare the non-linear optical component-containing polymer. Non-limiting examples of monomers including a chromophore group as the non-linear optical component include N-ethyl, N-4-dicyanomethylidenyl acrylate and N-ethyl, N-4-dicyanomethylidenyl-3,4,5,6,10-pentahydronaphtylpentyl acrylate.

The amount of chromophore in the photorefractive composition can vary. In an embodiment, chromophore is provided in the composition in an amount in the range of about 0.1% to about 70% based on the weight of the composition. In an embodiment, chromophore is provided in the composition in an amount in the range of about 5% to about 60% based on the weight of the composition. In an embodiment, chromophore is provided in the composition in an amount in the range of about 10% to about 50% based on the weight of the composition. In an embodiment, chromophore is provided in the composition in an amount in the range of about 20% to about 40% based on the weight of the composition.

The polymers described herein may be prepared in various ways, e.g., by polymerization of the corresponding monomers or precursors thereof. Polymerization may be carried out by methods known to a skilled artisan, as informed by the guidance provided herein. In some embodiments, radical polymerization using an azo-type initiator, such as AIBN (azoisobutyl nitrile), may be carried out. The radical polymerization technique makes it possible to prepare random or block copolymers comprising charge transport, sensitizer, and non-linear optical groups. Further, by following the techniques described herein, it is possible to prepare such materials with exceptionally good properties, such as photoconductivity and diffraction efficiency. In an embodiment of a radical polymerization method, the polymerization catalyst is generally used in an amount of from 0.01 mole % to 5 mole % or from 0.1 mole % to 1 mole % per mole of the total polymerizable monomers.

In some embodiments, radical polymerization can be carried out under inert gas (e.g., nitrogen, argon, or helium) and/or in the presence of a solvent (e.g., ethyl acetate, tetrahydrofuran, butyl acetate, toluene or xylene). Polymerization may be carried out under a pressure in the range of about 1 Kgf/cm² to about 50 Kgf/cm² or about 1 Kgf/cm² to about 5 Kgf/cm². In some embodiments, the concentration of total polymerizable monomer in a solvent may be about 0.99% to about 50% by weight, preferably about 2% to about 9.1% by weight. The polymerization may be carried out at a temperature in the range of about 50° C. to about 100° C., and may be allowed to continue for about 1 to about 100 hours, depending on the desired final molecular weight, polymerization temperature, and taking into account the polymerization rate.

Some embodiments provide a polymerization method involving the use of a precursor monomer with a functional group for non-linear optical ability for preparing the copolymers. The precursor may be represented by the following formula:

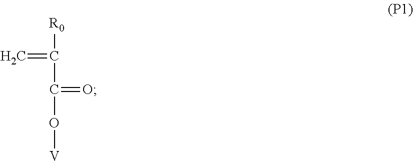

wherein R₀ in (P1) is hydrogen or methyl, and V in (P1) is a group selected from the formulae (V-1) and (V-2):

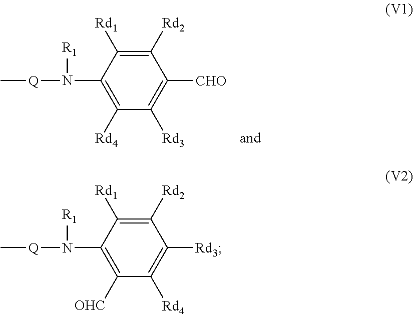

wherein each Q in (V1) and (V2) independently represents an alkylene group or a heteroalkylene group, the heteroalkylene group has one or more heteroatoms such as O and S; Rd₁-Rd₄ in (V1) and (V2) are each independently selected from the group consisting of hydrogen, linear or branched C₁-C₁₀ alkyl, and C₆-C₁₀ aryl, and R₁ in (V1) and (V2) is C₁-C₁₀ alkyl (branched or linear). In some embodiments, Q in (V1) and (V2) may independently be an alkylene group represented by (CH₂)ₚ where p is in the range of about 2 to about 6. In some embodiments, R₁ in (V1) and (V2) is independently selected from the group consisting of methyl, ethyl, propyl, butyl, pentyl and hexyl. In an embodiment, Rd₁-Rd₄ in (V1) and (V2) are hydrogen.

In some embodiments, the polymerization method for the precursor monomer can be carried out under conditions generally similar to those described above. After the precursor copolymer has been formed, it can be converted into the corresponding copolymer having non-linear optical groups and capabilities by a condensation reaction. In some embodiments, the condensation reagent may be selected from the group consisting of:

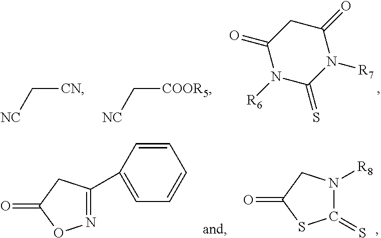

wherein R₅, R₆, R₇ and R₈ of the condensation reagents above are each independently selected from the group consisting of hydrogen, C₁-C₁₀ alkyl and C₆-C₁₀ aryl. The alkyl group may be either branched or linear.

In some embodiments, the condensation reaction between the precursor polymer and the condensation reagent can be carried out in the presence of a pyridine derivative catalyst at room temperature for about 1 to about 100 hrs. In some embodiments, a solvent, such as butyl acetate, chloroform, dichloromethane, toluene or xylene, can also be used. In some embodiments, the reaction may be carried out without the catalyst at a solvent reflux temperature of 30° C. or above for about 1 to about 100 hours.

Other chromophores that possess non-linear optical properties in a polymer matrix are described in U.S. Pat. No. 5,064,264 (incorporated herein by reference) and may also be used in some embodiments. Additional suitable materials known in the art may also be used, and are well described in the literature, such as D. S. Chemla & J. Zyss, “Nonlinear Optical Properties of Organic Molecules and Crystals” (Academic Press, 1987). U.S. Pat. No. 6,090,332 describes fused ring bridge and ring locked chromophores that can form thermally stable photorefractive compositions, which may be useful as well. The chosen compound(s) is sometimes mixed in the copolymer in a concentration of about 1% to about 50% by weight.

In some embodiments, the photorefractive composition further comprises a plasticizer. Any commercial plasticizer such as phthalate derivatives or low molecular weight hole transfer compounds (e.g., N-alkyl carbazole or triphenylamine derivatives or acetyl carbazole or triphenylamine derivatives) may be incorporated into the polymer matrix. An N-alkyl carbazole or triphenylamine derivative containing electron acceptor group is a suitable plasticizer that can help the photorefractive composition be more stable, as the plasticizer contains both N-alkyl carbazole or triphenylamine moiety and non-liner optical moiety in one compound.

Other non-limiting examples of the plasticizer include ethyl carbazole; 4-(N,N-diphenylamino)-phenylpropyl acetate; 4-(N,N-diphenylamino)-phenylmethyloxy a cetate; N-(acetoxypropylphenyl)-N,N′,N′-triphenyl-(1,1′-biphenyl)-4,4′-diamine; N-(acetoxypropylphenyl)-N′-phenyl-N,N′-di(4-methylphenyl)-(1,1′-biphenyl)-4,4′-diamine; and N-(acetoxypropylphenyl)-N′-phenyl-N,N′-di(4-buthoxyphenyl)-(1,1′-biphenyl)-4,4′-diamine. Such compounds can be used singly or in mixtures of two or more plasticizers. Also, un-polymerized monomers can be low molecular weight hole transfer compounds, for example 4-(N,N-diphenylamino)-phenylpropyl(meth)acrylate; N-[(meth)acroyloxypropylphenyl]-N,N′,N′-triphenyl-(1,1′-biphenyl)-4,4′-diamine; N-[(meth)acroyloxypropylphenyl]-N′-phenyl-N,N′-di(4-methylphenyl)-(1,1′-biphenyl)-4,4′-diamine; and N-[(meth)acroyloxypropylphenyl]- N′-phenyl-N,N′-di(4-buthoxyphenyl)-(1,1′-biphenyl)-4,4′-diamine. Such monomers can be used singly or in mixtures of two or more monomers.

In some embodiments, a plasticizer may be selected from N-alkyl carbazole or triphenylamine derivatives:

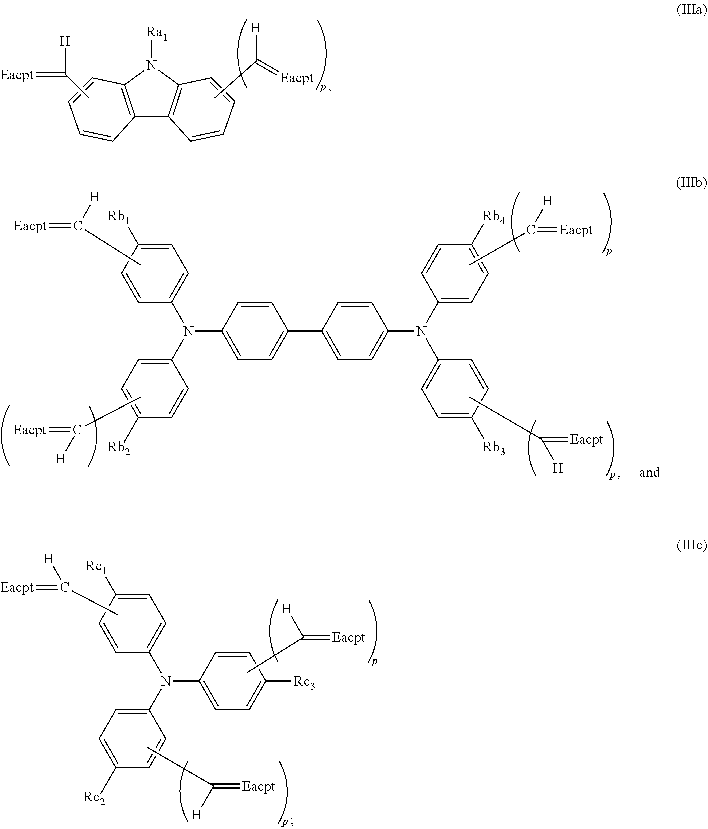

wherein Ra₁, Rb₁-Rb₄ and Rc₁-Rc₃ are each independently selected from the group consisting of hydrogen, branched or linear C₁-C₁₀ alkyl, and C₆-C₁₀ aryl; each p is independently 0 or 1; Eacpt is an electron acceptor group and is oxygen or represented by a structure selected from the group consisting of the structures;

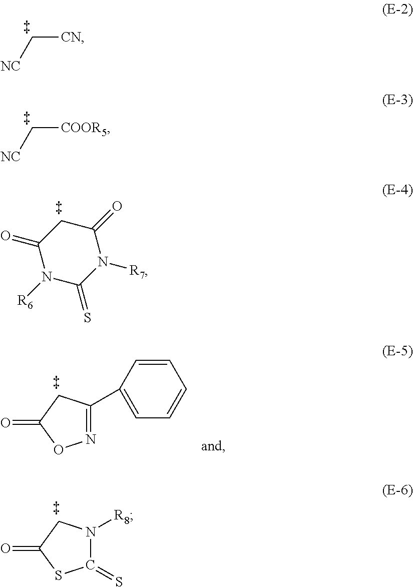

wherein R₅, R₆, R₇ and R₈ in formulae (E-3), (E-4) and (E-6) are each independently selected from the group consisting of hydrogen, linear or branched C₁-C₁₀ alkyl, and C₆-C₁₀ aryl.

In some embodiments, the photorefractive composition comprises a copolymer that provides photoconductive (charge transport) ability and non-linear optical ability. The photorefractive composition may also include other components as desired, such as plasticizer components. Some embodiments provide a photorefractive composition that comprises a copolymer. The copolymer may comprise a first repeating unit that includes a first moiety with charge transport ability, a second repeating unit including a second moiety with non-linear optical ability, and a third repeating unit that include a third moiety with plasticizing ability.

The ratio of different types of monomers used in forming the copolymer may be varied over a broad range. Some embodiments provide a photorefractive composition with a first repeating unit having charge transport ability and a second repeating unit having non-linear optical ability, with a weight ratio of the first repeating unit to the second repeating unit in the range of about 100:1 to about 0.5:1, preferably about 10:1 to about 1:1. When the weight ratio of such a first repeating unit to such a second repeating unit is smaller than about 0.5:1, the charge transport ability of copolymer may be too weak to give sufficient photorefractivity. However, even at such a low ratio, sufficient photorefractivity can still be provided by the addition of low molecular weight components having non-linear-optical ability (e.g., as described elsewhere herein). If the weight ratio for such a first repeating unit to such a second repeating unit is larger than about 100:1, the non-linear optical ability of the copolymer by itself may be too low to provide photorefractivity. However, even at such a high ratio, the addition of low molecular weight components having charge transport ability (e.g., as described elsewhere herein) can enhance photorefractivity.

In some embodiments, the molecular weight and the glass transition temperature, Tg, of the copolymer are selected to provide desirable physical properties. In some embodiments, it is valuable and desirable, although not essential, that the polymer is capable of being formed into films, coatings and shaped bodies of various kinds by standard polymer processing techniques (e.g., solvent coating, injection molding or extrusion).

In some embodiments, the polymer has a weight average molecular weight, Mw, in the range of from about 3,000 to about 500,000, preferably in the range from about 5,000 to about 100,000. The term “weight average molecular weight” as used herein means the value determined by the GPC (gel permeation chromatography) method using polystyrene standards, as is well known in the art. In some embodiments, additional benefits may be provided by lowering the dependence on plasticizers. By selecting copolymers with intrinsically moderate Tg and by using methods that tend to depress the average Tg, it is possible to limit the amount of plasticizer in the composition to no more than about 30% or 25%, and in some embodiments, no more than about 20%. In some embodiments, the photorefractive composition that can be activated by a visible light laser beam may have a thickness of about 105 μm and a transmittance of higher than about 30%, more preferably from about 40% to about 90%. If the photorefractive composition has a transmittance of higher than about 30% at a thickness of 105 μm when irradiated by a visible light laser beam, the laser beam can smoothly pass through the composition to form grating image and signals.

An embodiment provides a photorefractive composition that modulates light upon irradiation by a visible light laser beam, wherein the photorefractive composition comprises a polymer comprising a first repeating unit that includes at least one moiety selected from the group consisting of the formulae (Ia), (Ib) and (Ic) as defined above. In some embodiments, the polymer may further comprise a second repeating unit comprising at least one moiety selected from formula (IIa) and chromophores. In some embodiments, the polymer may further comprise a repeating unit of formula (IIa′). In some embodiments, the polymer may further comprise a third repeating unit that includes at least one moiety selected from formulae (IIIa), (IIIb) and (IIIc).

Many currently available photorefractive polymers have poor phase stabilities and can become hazy after days. Where the film composition comprising the photorefractive polymer shows significant haziness, poor photorefractive properties are typically exhibited. The haziness of the film composition usually results from incompatibilities between several photorefractive components. For example, photorefractive compositions containing both charge transport ability components and non-linear optical components may exhibit haziness because the components having charge transport ability are usually hydrophobic and non-polar, whereas components having non-linear optical ability are usually hydrophilic and polar. As a result, the natural tendency of the composition is to phase separate, thus causing haziness.

However, preferred embodiments presented herein show good phase stability and gave no haziness, even after several months. Such compositions retain good photorefractive properties, as the compositions are very stable and exhibit little or no phase separation. Without being bound by theory, the stability is likely attributable to the sensitizer structures and/or combination of sensitizer and chromophore in the photorefractive composition. In addition, the matrix polymer system is a copolymer of components having charge transport ability and components having non-linear optics ability. That is, the components having charge transport ability and the components having non-linear optical ability coexist in one polymer chain, therefore rendering significant detrimental phase separation difficult and unlikely.

Furthermore, although heat usually increases the rate of phase separation, preferred compositions described herein exhibit good phase stability, even after being heated. In accelerated heat testing, test samples heated at about 40° C., about 60° C., about 80° C., and about 120° C. are found to be stable after days, weeks, and sometimes even after 6 months. The good phase stability allows the copolymer to be further process and incorporated into optical device applications for various commercial products. In an embodiment, the optical device is photorefractive upon irradiation by a visible light laser beam. In an embodiment, the optical device comprises a photorefractive composition in which a grating can be written without applying external bias voltage. In an embodiment, a grating signal can be read out of the photorefractive composition without applying external bias voltage.

For preferred photorefractive devices, usually the thickness of a photorefractive layer is in the range of about 10 μm to about 200 μm. Preferably, the thickness range is in the range of about 30 μm to about 150 μm. In many cases, if the sample thickness is less than 10 μm, the diffracted signal is not desired Bragg Refraction region, but Raman-Nathan Region which can not show proper grating behavior. On the other hand, if the sample thickness is greater than 200 μm, the amount of bias voltage that is typically needed to show grating behavior would be greater than desired. Also, composition transmittance for laser beams can often be reduced significantly and result in little or no grating signals.

In some embodiments, the composition is configured to transmit about 500 nm to about 700 nm wave length laser beam. The composition transmittance depends on the photorefractive layer thickness, thus by controlling the thickness of the photorefractive layer comprising a photorefractive composition, the light modulating characteristics can be adjusted as desired. When the transmittance is low, the laser beam may not pass through the layer to form grating image and signals. On the other hand, if the absorbance is 0%, no laser energy can be absorbed to generate grating signals. In some embodiments, the suitable range of transmittance is about 10% to about 99.99%, about 30% to about 99.9%, or about 35% to about 90%. Linear transmittance was performed to determine the absorption coefficient of the photorefractive device. For measurements, a photorefractive layer was irradiated to a 532 nm laser beam with an incident path perpendicular to the layer surface. The beam intensity before and after passing through the photorefractive layer is monitored and the linear transmittance of the sample is given by:

$$T = \frac{{I}_{Transmitted}}{{I}_{incident}}$$

The wavelength of the laser is not particularly restricted, but is usually in the range of about 500 nm to about 700 nm. Typically, as a laser light source, a widely available 532 nm laser can be used.

One of the various advantages of preferred photorefractive compositions described herein is a long grating holding time. Longer grating holding enables the photorefractive composition to be used for applications such as holographic data storage and image recording. In an embodiment, the grating holding time is one hour or more. In an embodiment, the grating holding time is four hours or more. In an embodiment, the grating holding time is one day or more. In an embodiment, the grating holding time is two days or more. In an embodiment, the grating holding time is one week or more. In an embodiment, the grating holding time is one month or more. In an embodiment, the grating holding time is six months or more. In an embodiment, the grating holding time is one year or more. In an embodiment, the grating holding time is several years. In an embodiment, the grating holding time is nearly permanent, e.g., ten years or longer.

The grating can be written into the photorefractive composition with or without using an external electric field (expressed as bias voltage). Additionally, a grating signal can be read out of the photorefractive composition with or without applying an external bias voltage. The ability to read and/or write signals using little or no external bias voltage can be achieved by appropriate selection of the type and amount of sensitizer used in the photorefractive compositions described herein. In some embodiments, the photorefractive compositions described herein have demonstrated grating holding time from minutes to hours at a zero bias voltage.

An additional advantage of the preferred photorefractive compositions is the high diffraction efficiency, η, that can be achieved. Diffraction efficiency is defined as the ratio of the intensity of a diffracted beam to the intensity of an incident probe beam, and is determined by measuring the intensities of the respective beams. A device is more effective, the closer the ratio is to 100%. In general, for a given photorefractive composition, a higher diffraction efficiency can be achieved by increasing the applied biased voltage. The samples of embodiments described herein could provide at least about 40% and even about 50% of the diffraction efficiency.

The embodiments are now further described by the following examples, which are intended to be illustrative of the invention, but are not intended to limit the scope or underlying principles in any way.

### EXAMPLE 1

### (a) Monomers Containing Charge Transport Groups

TPD acrylate type charge transport monomers (N-[acroyloxypropylphenyl]-N,N′,N′-triphenyl-(1,1′-biphenyl)-4,4′-diamine) (TPD acrylate) were purchased from Fuji Chemical, Japan. The TPD acrylate type monomer possessed the structure:

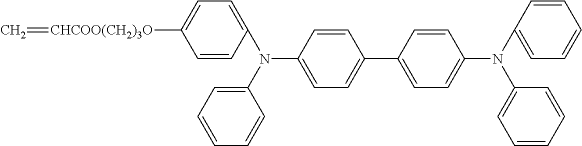

### (b) Monomers Containing Non-Linear Optical Groups

The non-linear-optical precursor monomer 5-[N-ethyl-N-4-formylphenyl]amino-pentyl acrylate was synthesized according to the following synthesis scheme:

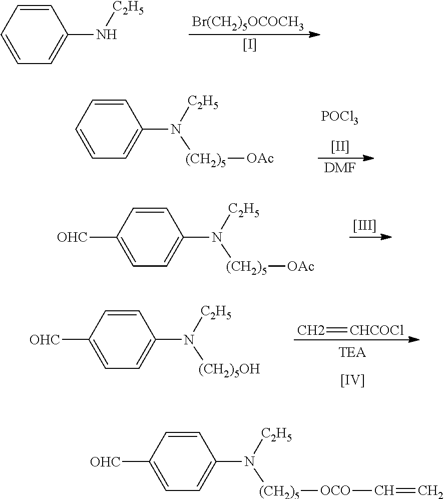

STEP I: Bromopentyl acetate (5 mL, 30 mmol), toluene (25 mL), triethylamine (4.2 mL, 30 mmol), and N-ethylaniline (4 mL, 30 mmol) were added together at room temperature. The mixture was heated at 120° C. overnight. After cooling down, the reaction mixture was rotary-evaporated to form a residue. The residue was purified by silica gel chromatography (developing solvent: hexane/acetone=9/1). An oily amine compound was obtained. (Yield: 6.0 g (80%))

STEP II: Anhydrous DMF (6 mL, 77.5 mmol) was cooled in an ice-bath. Then, POCl₃ (2.3 mL, 24.5 mmol) was added dropwise into the cooled anhydrous DMF, and the mixture was allowed to come to room temperature. The amine compound (5.8 g, 23.3 mmol) was added through a rubber septum by syringe with dichloroethane. After stirring for 30 min., the reaction mixture was heated to 90° C. and the reaction was allowed to proceed overnight under an argon atmosphere. After the overnight reaction, the reaction mixture was cooled and poured into brine water and extracted by ether. The ether layer was washed with potassium carbonate solution and dried over anhydrous magnesium sulfate. After removing the magnesium sulfate, the solvent was removed and the residue was purified by silica gel chromatography (developing solvent: hexane/ethyl acetate=3/1). An aldehyde compound was obtained. (Yield: 4.2 g (65%))

STEP III: The aldehyde compound (3.92 g, 14.1mmol) was dissolved in methanol (20 mL). Into the solution, potassium carbonate (400 mg) and water (1 mL) were added at room temperature and the solution was stirred overnight. Next, the solution was poured into brine water and extracted by ether. The ether layer was dried over anhydrous magnesium sulfate. After removing the magnesium sulfate, the solvent was removed and the residue was purified by silica gel chromatography (developing solvent: hexane/acetone=1/1). An aldehyde alcohol compound was obtained. (Yield: 3.2 g (96%))

STEP IV: The aldehyde alcohol (5.8 g, 24.7 mmol) was dissolved in anhydrous THF (60 mL). Into the solution, triethylamine (3.8 mL, 27.1 mmol) was added and the solution was cooled by ice-bath. Acrolyl chloride (2.1 mL, 26.5 mmol) was added and the solution was maintained at 0° C. for 20 minutes. Thereafter, the solution was allowed to warm up to room temperature and stirred at room temperature for 1 hour, at which point TLC indicated that all of the alcohol compound had disappeared. The solution was poured into brine water and extracted by ether. The ether layer was dried over anhydrous magnesium sulfate. After removing the magnesium sulfate, the solvent was removed and the residue acrylate compound was purified by silica gel chromatography (developing solvent: hexane/acetone=1/1). The compound yield was 5.38g (76%), and the compound purity was 99% (by GC).

### (c) Chromophore

NPP ((s)-(−)-1-(4-nitrophenyl)-2-pyrrolidinemethanol, 98%.) is commercially available from Aldrich and is used after recrystallization from ethanol.

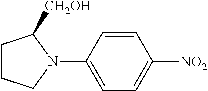

### (d) Plasticizer

N-ethylhexylcarbazole is commercially available from Aldrich and is used as received.

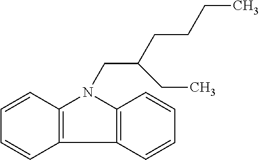

### (e) Sensitizer

Anthraquinone and 2-nitro-9-fluorenone sensitizer are both commercially available from Aldrich and are used as received.

### EXAMPLE 2

### Preparation of Copolymer by AIBN Radical Initiated Polymerization (TPD Acrylate/Chromophore Type 10:1)

The charge transport monomer N-[(meth)acroyloxypropylphenyl]-N,N′,N′-triphenyl-(1,1′-biphenyl)-4,4′-diamine (TPD acrylate) (43.34 g), and the non-linear optical precursor monomer 5-[N-ethyl-N-4-formylphenyl]amino-pentyl acrylate (4.35 g), prepared as described in Example 1, were put into a three-necked flask. After toluene (400 mL) was added and purged by argon gas for 1 hour, azoisobutylnitrile (118 mg) was added into the solution. Then, the solution was heated to 65° C., while continuing to purge with argon gas.

After 18 hrs of polymerization, the polymer solution was diluted with toluene. The polymer was precipitated from the solution and added to methanol, then the resulting polymer precipitate was collected and washed in diethyl ether and methanol. The white polymer powder was collected and dried. The yield of polymer was 66%.

The weight average and number average molecular weights were measured by gel permeation chromatography, using polystyrene standard. The results were Mn=10,600, Mw=17,100, giving a polydispersity of 1.61.

### EXAMPLE 3

### Preparation of TPD Acrylate Polymer by AIBN Radical Initiated Polymerization

The charge transport monomer N-[(meth)acroyloxypropylphenyl]-N,N′,N′-triphenyl-(1,1′-biphenyl)-4,4′-diamine (TPD acrylate) (61.50 g) was put into a three-necked flask. Toluene (400 mL) was added and purged by argon gas for 1 hour, and then azoisobutylnitrile (138 mg) was added into this solution. The solution was heated to 65° C., while continuing to purge with argon gas.

After 18 hours of polymerization, the polymer solution was diluted with toluene. The polymer was precipitated from the solution and added to methanol, and then the resulting polymer precipitate was collected and washed in diethyl ether and methanol. The white polymer powder was collected and dried. The yield of polymer was 78%.

The weight average and number average molecular weights were measured by gel permeation chromatography, using polystyrene standard. The results were Mn=20,400, Mw=42,900, giving a polydispersity of 2.10.

### EXAMPLE 4

### Preparation of Photorefractive Composition

A photorefractive composition testing sample was prepared. The components of the composition were provided in approximate amounts as follows:
(i) Matrix polymer (described in Example 2): 47.18 wt %
(ii) NPP chromophore 24.81 wt %
(iii) Ethylhexyl carbazole plasticizer 24.98 wt %
(iv) Anthraquinone sensitizer 3.03 wt %

To prepare the composition, the components listed above were dissolved in dichloromethane with stirring and then dripped onto glass plates at 60° C. using a filtered glass syringe. The composites were then cooked at 60° C. for five minutes and then vacuumed for five minutes. The composites were then cooked at 150° C. for five minutes and then vacuumed 30 seconds. The composites were then scrapped and cut into chunks. Small portions of this chunk were taken off and sandwiched between indium tin oxide (ITO) coated glass plates separated by a 105 μm spacer to form the individual samples.

### Measurement 1—Diffraction Efficiency

The diffraction efficiency was measured at 532 nm by two beam coupling experiments using a laser beam. Two beam coupling experiments were done by using two writing beams forming an angle of 20.5 degrees in the air, with the bisector of the writing beams making an angle of 60 degrees relative to the sample normal. Two split p-polarized writing beams with equal intensity of 20 mW in the sample were used, and the beam spot diameter was about 2 mm. The laser intensity irradiated to the sample was about 0.67 W/cm². Without applying an external voltage, energy transfer (two beam coupling) between two p-polarized beams was observed. After 10 minutes of writing a grating, one of the writing beams was blocked.

The transmitted signal and the diffracted signal from the other beam each were monitored by photodetectors to determine the diffraction efficiency. The grating signal was read out without applying external bias voltage. The Diffraction efficiency (η) was calculated by

η=I_{diffracted signal}/(I_{diffracted signal}+I_{transmitted signal})

### Measurement 2—Transmittance

The thickness of the composition was 105 μm. For measurements, a photorefractive layer was irradiated with a 532 nm laser beam having an incident path perpendicular to the layer surface. The beam intensity before and after passing through the photorefractive layer is monitored and the linear transmittance of the sample is given by:

$$T = \frac{{I}_{Transmitted}}{{I}_{incident}}$$

No external bias voltage was used in either writing the grating into the composition or reading the grating signal afterward. Nonetheless, the composition of Example 4 exhibited good diffraction efficiency (even after an hour) and good transmittance properties. The measured performance for Example 4 was as follows:
Diffraction efficiency (%): 22%
Diffraction efficiency (%) after 60 min: 14%
Transmittance at 532 nm: 38%

### EXAMPLE 5

### Preparation of Photorefractive Composition

A photorefractive composition testing sample was prepared. The components of the composition were provided in approximate amounts as follows:
(i) Matrix polymer (described in Example 3): 46.76 wt %
(ii) NPP chromophore 25.17 wt %
(iii) Ethylhexyl carbazole plasticizer 24.63 wt %
(iv) Anthraquinone sensitizer 3.44 wt %

A grating was written into the composition of Example 5 and a grating signal was read out in a similar manner as in Example 4 (no external bias voltage used in either step). Once again, the composition exhibited good diffraction efficiency (even after an hour) and good transmittance properties. The measured performance for Example 5 was as follows:
Initial diffraction efficiency (%): 13%
Diffraction efficiency (%) after 25 min: 12%
Transmittance at 532 nm: 32%

### EXAMPLE 6

### Preparation of Photorefractive Composition

A photorefractive composition testing sample was prepared. The components of the composition were provided in approximate amounts as follows:
(i) Matrix polymer (described in Example 3): 36.36 wt %
(ii) NPP chromophore 19.34 wt %
(iii) Ethylhexyl carbazole plasticizer 41.97 wt %
(iv) Anthraquinone sensitizer 2.32 wt %

A grating was written into the composition of Example 6 and a grating signal was read out in a similar manner as in Example 4 (no external bias voltage used in either step). Once again, the composition exhibited good diffraction efficiency (even after an hour) and good transmittance properties. The measured performance for Example 6 was as follows:
Initial diffraction efficiency (%): 50%
Diffraction efficiency (%) after 40 min: 11%
Transmittance at 532 nm: 51%

### EXAMPLE 7

### Preparation of Photorefractive Composition

A photorefractive composition testing sample was prepared. The components of the composition were provided in approximate amounts as follows:
(i) Matrix polymer (described in Example 3): 45.90 wt %
(ii) NPP chromophore 24.41 wt %
(iii) Ethylhexyl carbazole plasticizer 26.46 wt %
(iv) 2-nitro-9-fluorenone sensitizer 3.22 wt %

A grating was written into the composition of Example 7 and a grating signal was read out in a similar manner as in Example 4 (no external bias voltage used in either step). The measured performance for Example 7 was as follows:
Initial diffraction efficiency (%): 2%
Diffraction efficiency (%) after 20 min: 1%
Transmittance at 532 nm: 39%

### COMPARATIVE EXAMPLE 1

### Preparation of Photorefractive Composition

A photorefractive composition was obtained in the same manner as in the Example 4, except using different composition components. No sensitizer was provided. The components of the composition were as follows:
(i) Matrix polymer (described in Example 2): 50 wt %
(ii) 7-FDCST chromophore: 30 wt %
(iii) Ethylhexyl carbazole plasticizer: 20 wt %

While the composition had good transmittance, a grating signal was only seen upon the application of external bias voltage. The measured properties for Comparative Example 1 were as follows:
Initial diffraction efficiency (%): no signal without external bias voltage
Transmittance at 532 nm: 35%

### COMPARATIVE EXAMPLE 2

### Preparation of Photorefractive Composition

A photorefractive composition was obtained in the same manner as in the Example 4, except using different composition components. No sensitizer was provided. The components of the composition were as follows:
(i) Matrix polymer (described in Example 2): 50 wt %
(ii) NPP chromophore: 30 wt %
(iii) Ethylhexyl carbazole plasticizer: 20 wt %

While the composition had good transmittance, a grating signal was only seen upon the application of external bias voltage. The measured properties for Comparative Example 2 were as follows:
Initial diffraction efficiency (%): no signal without external bias voltage
Transmittance at 532 nm: 60%

As shown in the comparative examples, the grating does not form and a grating signal cannot be read out unless external bias voltage is applied. Diffraction efficiency is only observed in Comparative Example 1 and Comparative Example 2 after an external bias voltage was applied.

All literature references and patents mentioned herein are hereby incorporated in their entireties. Although the foregoing description has shown, described, and pointed out the fundamental novel features of the present teachings, it will be understood that various omissions, substitutions, and changes in the form of the detail of the apparatus as illustrated, as well as the uses thereof, can be made by those skilled in the art, without departing from the scope of the present teachings. Consequently, the scope of the present teachings should not be limited to the foregoing discussion, but should be defined by the appended claims.

1. A method of forming a grating in a photorefractive composition, comprising:
providing a photorefractive composition comprising a sensitizer and a polymer, wherein the sensitizer comprises at least one selected from the group consisting of anthraquinone, 2-nitro-9-fluorenone and 2,7-dinitro-9-fluorenone, wherein the polymer comprises a first repeating unit that includes a moiety selected from the group consisting of the following structures (Ia), (Ib) and (Ic): 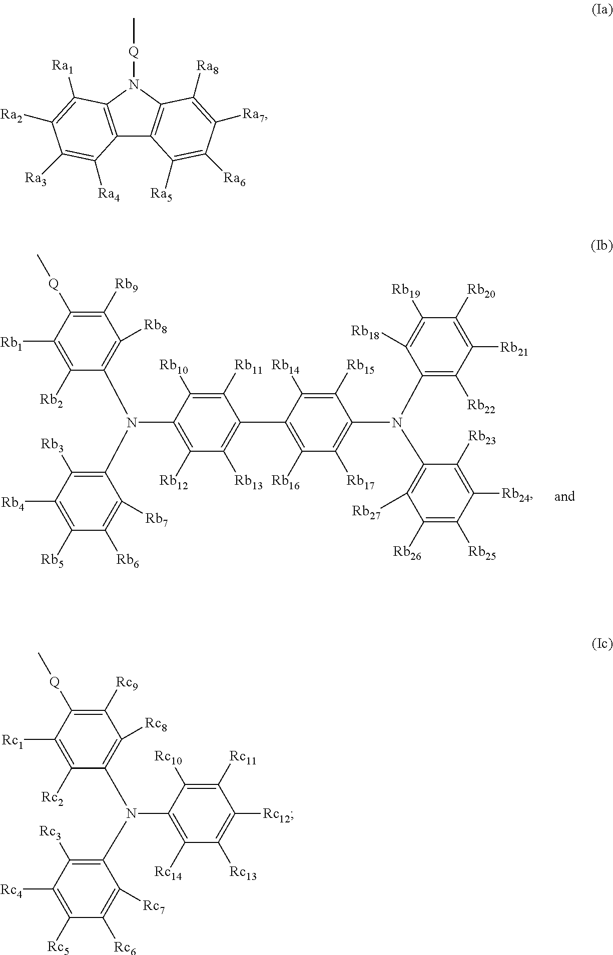
wherein each Q in formulae (Ia), (Ib) and (Ic) independently represents an alkylene or a heteroalkylene; Ra₁-Ra₈, Rb₁-Rb₂₇, and Rc₁-Rc₁₄ in formulae (Ia), (Ib), and (Ic) are each independently selected from the group consisting of hydrogen, linear or branched optionally substituted C₁-C₁₀ alkyl or heteroalkyl, and optionally substituted C₆-C₁₀ aryl; and
irradiating the photorefractive composition with a visible light laser beam without applying an external bias voltage to provide the grating.

2. The method of claim 1, wherein the visible light laser beam has a wavelength of about 500 nm to about 700 nm.

3. The method of claim 1, wherein the photorefractive composition has a transmittance of higher than about 30% at a thickness of 105 μm when irradiated by the visible light laser beam.

4. The method of claim 1, wherein the photorefractive composition further comprises a plasticizer.

5. The method of claim 1, wherein the photorefractive composition further comprises a chromophore.

6. A photorefractive composition that modulates light upon irradiation by a visible light laser beam comprising a sensitizer and a polymer, wherein the sensitizer comprises at least one selected from the group consisting of anthraquinone, 2-nitro-9-fluorenone and 2,7-dinitro-9-fluorenone, wherein the polymer comprises a first repeating unit which includes at least one moiety selected from the group consisting of the following formulae (Ia), (Ib) and (Ic): 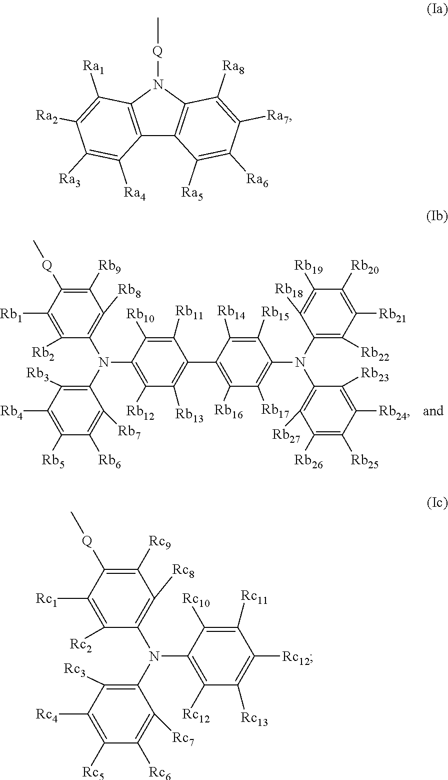
wherein each Q in formulae (Ia), (Ib) and (Ic) independently represents an alkylene or a heteroalkylene; Ra₁-Ra₈, Rb₁-Rb₂₇, and Rc₁-Rc₁₄ in formulae (Ia), (Ib), and (Ic) are each independently selected from the group consisting of hydrogen, linear or branched optionally substituted C₁-C₁₀ alkyl or heteroalkyl, and optionally substituted C₆-C₁₀ aryl; and
wherein the composition is formulated to be capable of providing a grating without external bias voltage.

7. The composition of claim 6, wherein the polymer further comprises a second repeating unit which includes a moiety represented by the following formula (IIa): 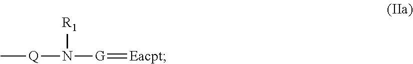
wherein Q in formula (IIa) represents an alkylene group or a heteroalkylene group; R₁ in formula (IIa) is selected from the group consisting of hydrogen, linear C₁-C₁₀ alkyl, branched C₁-C₁₀ alkyl, and C₆-C₁₀ aryl; G in formula (IIa) is a π-conjugated group; and Eacpt in formula (IIa) is an electron acceptor group.

8. The composition of claim 7, wherein the second repeating unit is represented by the following formula (IIa′): 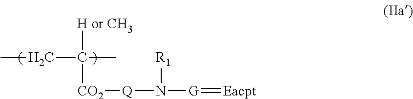
wherein Q in formula (IIa′) represents an alkylene group or a heteroalkylene group; R₁ in formula (IIa′) is selected from the group consisting of hydrogen, linear C₁-C₁₀ alkyl, branched C₁-C₁₀ alkyl, and C₆-C₁₀ aryl; G in formula (IIa′) is a π-conjugated group; and Eacpt in formula (IIa′) is an electron acceptor group.

9. The composition of claim 7, wherein G in formulae (IIa) and (IIa′) is represented by a structure selected from the group consisting of the following formulae (G-1) and (G-2): 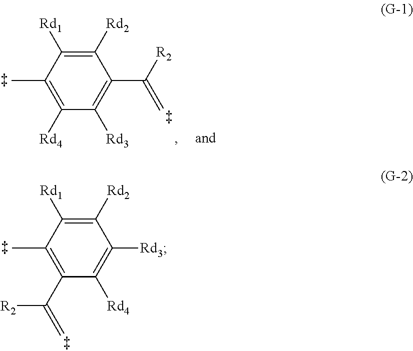
wherein Rd₁-Rd₄ in formulae (G-1) and (G-2) are each independently selected from the group consisting of hydrogen, linear C₁-C₁₀ alkyl, branched C₁-C₁₀ alkyl, C₆-C₁₀ aryl, and halogen; and R₂ in formulae (G-1) and (G-2) is independently selected from the group consisting of hydrogen, linear C₁-C₁₀ alkyl, branched C₁-C₁₀ alkyl, and C₆-C₁₀ aryl.

10. The composition of claim 7, wherein Eacpt in formulae (IIa) and (IIa′) is represented by oxygen or a structure selected from the group consisting of the following formulae (E-2) to (E-6): 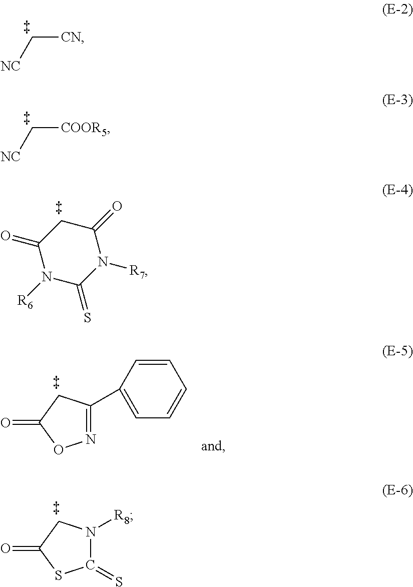
wherein R₅, R₆, R₇ and R₈ in formulae (E-3), (E-4), and (E-6) are each independently selected from the group consisting of hydrogen, linear C₁-C₁₀ alkyl, branched C₁-C₁₀ alkyl, and C₆-C₁₀ aryl.

11. The composition of claim 6, wherein the composition further comprises a plasticizer.

12. The composition of to claim 6, wherein the composition further comprises a chromophore.

13. The composition of claim 6, wherein the first repeating unit is selected from the group consisting of the following formulae (Ia′), (Ib′) and (Ic′): 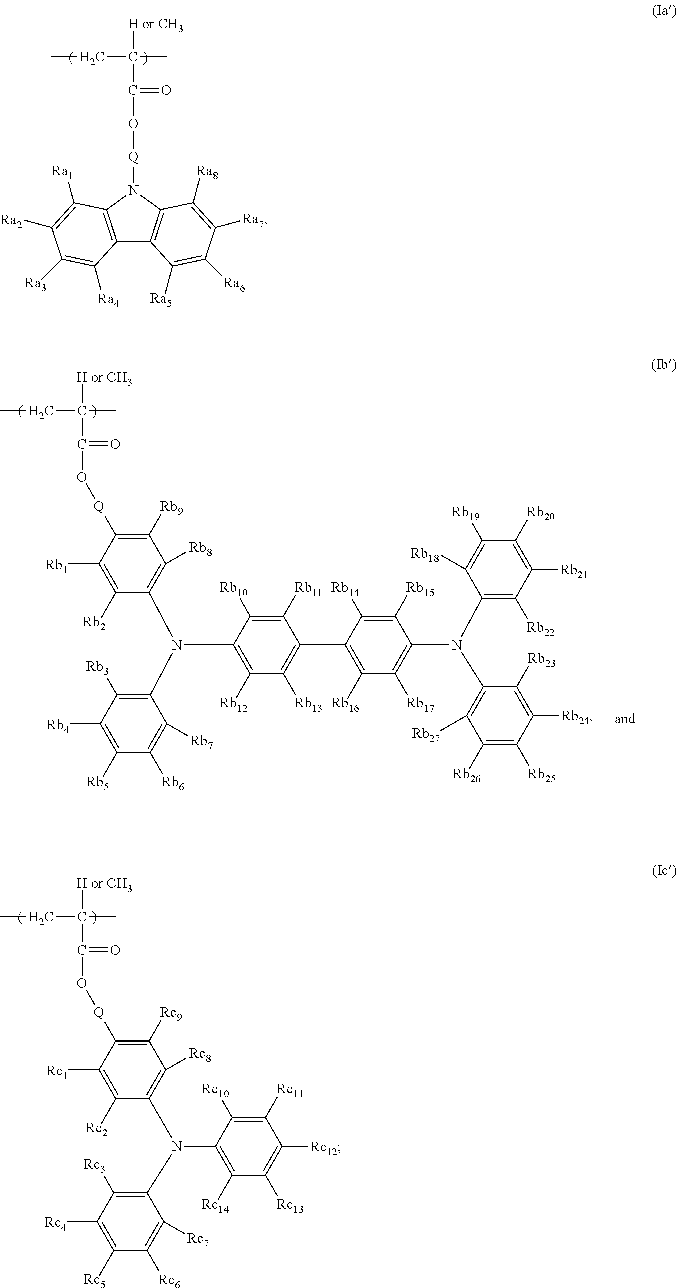
wherein each Q in formulae (Ia′), (Ib′) and (Ic′) independently represents an alkylene group or a heteroalkylene group; Ra₁-Ra₈, Rb₁-Rb₂₇ and Rc₁-Rc₁₄ in formulae (Ia′), (Ib′) and (Ic′) are each independently selected from the group consisting of hydrogen, linear or branched optionally substituted C₁-C₁₀ alkyl or heteroalkyl, and optionally substituted C₆-C₁₀ aryl.

14. The composition of claim 6, wherein the composition has a transmittance of higher than about 30% at a thickness of 105 μm when irradiated by the visible light laser beam.

15. The composition of claim 6, wherein the composition is photorefractive upon irradiation by a laser beam having a wavelength in the range of about 500 nm to about 700 nm.

16. An optical device comprising the composition of claim 6, wherein said optical device is photorefractive upon irradiation by a visible light laser beam, and wherein said optical device provides a grating without applying external bias voltage.
